(19) United States
(12) Patent Application Publication
(10) Pub. No.: US 2006/0016781 A1
(43) Pub. Date: Jan. 26, 2006

(54) Dry etching method

(76) Inventors: Kenichi Kuwabara, Hikari-shi (JP); Yasuhiro Nishimori, Kudamatsu-shi (JP); Masunori Ishihara, Kudamatsu-shi (JP); Satoshi Une, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/928,266

(22) Filed: Aug. 30, 2004

(30) Foreign Application Priority Data
Jul. 26, 2004 (JP) 2004-217390
Aug. 2, 2004 (JP) 2004-225668

(51) Int. Cl. H01L 21/302; C23F 1/00

(52) U.S. Cl. 216/41; 216/58; 438/706; 216/17

(57) ABSTRACT

The object of the invention is to provide a dry etching method for processing the edge portion of a hard mask to have a round profile. The present method for manufacturing a semiconductor device comprises (b) forming a silicon nitride film 12 mask using a patterned photoresist 13, (c) cutting back the photoresist 13 via dry etching, and (d) etching the exposed edge portion of the silicon nitride film mask 12, to thereby enable trench processing using a silicon nitride film mask 12 having a rounded edge portion.

The present application is based on and claims priority of Japanese patent application No. 2004-217390 filed on Jul. 26, 2004 and No. 2004-225668 filed on Aug. 2, 2004, the entire contents of which are hereby incorporated by reference.

### FIELD OF THE INVENTION

The present invention relates to a method for etching a semiconductor device. More specifically, the present invention relates to a dry etching method for processing an edge portion of a hard mask to form an edge with a round profile.

### DESCRIPTION OF THE RELATED ART

Recently, a method called shallow trench isolation (STI) is adopted as a method for isolating elements on a semiconductor device. This method is for electrically isolating elements by forming a trench in the element isolation region on the silicon substrate surface via dry etching, and embedding an insulating film in the trench via low-pressure high-density plasma CVD method or the like.

Along with the miniaturization and enhanced integration of the semiconductor devices, the aspect ratio of the trenches of the STI has become higher, by which a problem occurs in which cavities are formed in the insulating film during the embedding process according to the low-pressure high-density plasma CVD method due to the limitation of the embedding performance.

One known method for solving this problem is to process an edge portion of the upper area of a hard mask formed of an inorganic material such as a silicon nitride film disposed on the uppermost layer of the STI trench so that the edge has a round profile. It is known that by rounding the edge portion of the hard mask, the embedding performance of the low-pressure high-density plasma CVD method is improved and the occurrence of a cavity during the embedding process can be suppressed.

As a method for processing an organic material using ions and radicals in a plasma, there is proposed a method for trimming an organic material having small pattern density dependence, comprising etching an organic material film in an etching atmosphere including oxygen-containing gas, chlorine-containing gas and bromine-containing gas, thereby generating CBrx, depositing the same on the surface of an object to be processed and etching the same (refer for example to Japanese Patent Application Laid-Open No. 2001-196355).

The method disclosed in the above-mentioned patent document 1 is not related to exposing an edge portion of a hard mask such as a silicon nitride film formed as a base of the photoresist and processing the edge to form a round profile. According further to the prior art method, the photoresist is removed prior to the process of forming the trench for STI, so the thickness of the film is reduced by the etching performed during the trench formation process, and a problem occurs in which the initial thickness of the silicon nitride mask is reduced. Moreover, according to the prior art method, the round profile of the edge portion depends on the etching conditions for forming the trench of the STI, so it was difficult to control the profile.

### SUMMARY OF THE INVENTION

The object of the present invention is to provide a round profile processing to the edge portion of the silicon nitride film mask while maintaining the initial film thickness of the mask and to independently control the round profile of the mask edge portion, thereby improving the processing accuracy.

This object is achieved by forming a mask by a silicon nitride film using a patterned photoresist as the mask, cutting back the photoresist pattern via dry etching, and etching a predetermined amount of an edge portion of the silicon nitride film mask exposed by cutting back the photoresist.

According to the present processing method, the etching process is performed with the resist mask remaining on the silicon nitride film, so the initial thickness of the silicon nitride film mask will not be reduced by etching. Since it is possible to ensure a determined amount of silicon nitride film mask used as the stopper film for a chemical-mechanical polishing (CMP) process, control of the CMP process is facilitated. Moreover, since the round profile of the mask edge portion can be controlled independently, the process accuracy of the round profile processing is improved, and thus the occurrence of a cavity during the embedding step can be suppressed.

In other words, according to the present invention, the edge portion of the silicon nitride film mask can be processed to have a round profile while maintaining the initial film thickness of the silicon nitride film, and the round profile of the silicon nitride film can be independently controlled via the step of cutting back the resist mask, so the process accuracy of the round profile can be improved.

### BRIEF DESCRIPTION OF THE DRAWINGS

FIG. 1 is a schematic cross-sectional view of the microwave plasma etching apparatus used in a preferred embodiment of the present invention;

FIG. 2 is a cross-sectional view showing the main portion of a semiconductor substrate for describing the dry etching method according to the present invention, wherein 2(a) shows the step of forming a resist film, 2(b) shows the step of forming a silicon nitride film, 2(c) shows the step of trimming the resist, 2(d) shows the step of forming a rounded edge to the silicon film mask, 2(e) shows the step of processing a trench for STI, and 2(f) shows the step of removing the resist; and

FIG. 3 is a view showing the relationship between the time of the cutback step of the present invention and the rounding width of the edge of the silicon nitride film.

### DETAILED DESCRIPTION OF THE PREFERRED EMBODIMENT

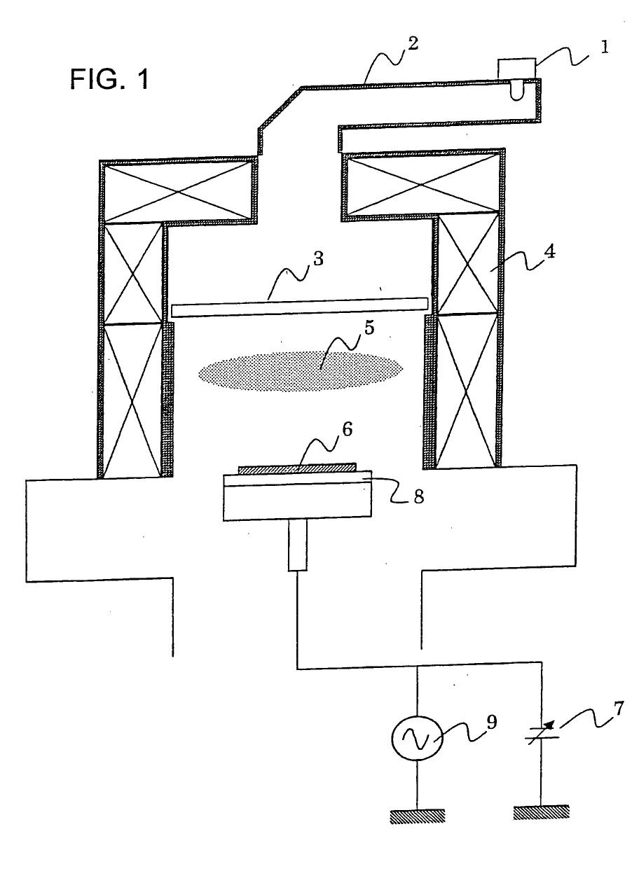

The plasma etching method according to the present invention will now be explained. FIG. 1 shows an etching apparatus used in the present invention. The present embodiment is an example in which a microwave plasma etching apparatus utilizing microwaves and magnetic field as plasma generating means is applied. Microwaves are generated by a magnetron 1, sent via a waveguide 2 and passed through a quartz plate 3 to be radiated into a vacuum vessel. A solenoid coil 4 is disposed around the vacuum vessel, and a magnetic field created via the coil and the radiated microwaves cause an electron cyclotron resonance (ECR). Thereby, a process gas is effectively turned into plasma 5 having high density. A process wafer 6 is held on an electrode via electrostatic chucking force, by applying a DC voltage to a wafer stage 8 from an electrostatic chucking power supply 7. Moreover, an RF power supply 9 is connected to the electrode for applying RF power (RF bias) to the electrode so as to provide to the ions in the plasma an acceleration potential in the direction perpendicular to the wafer. After etching, the gas is evacuated through an evacuation port provided to the bottom area of the apparatus via a turbo pump or dry pump (not shown).

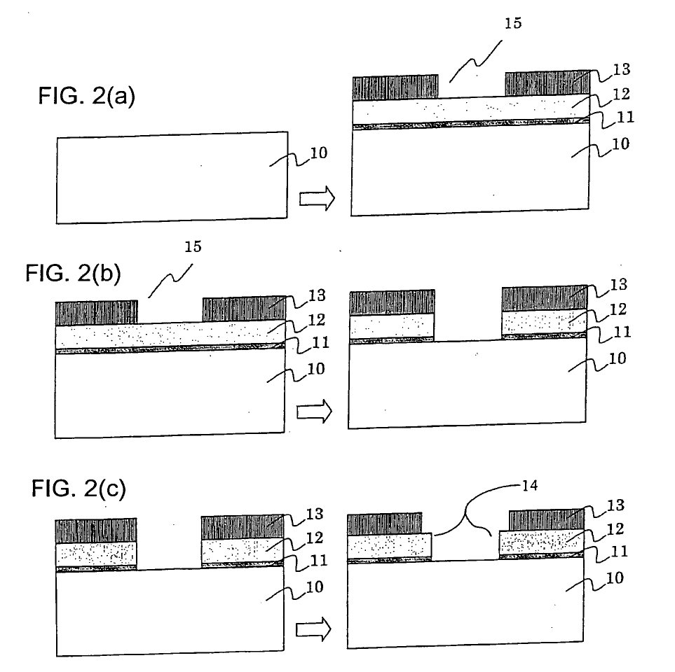

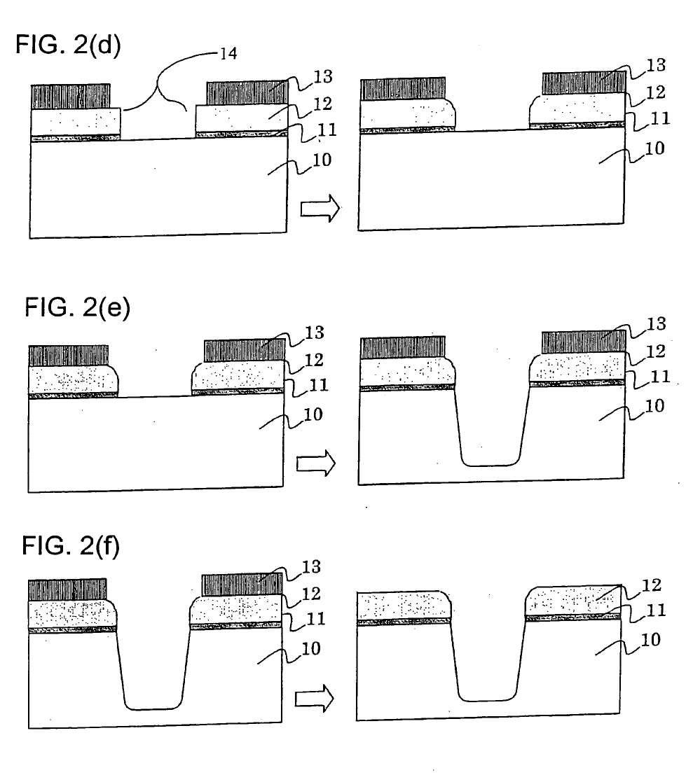

FIG. 2 is a view showing the method for manufacturing a semiconductor device using the apparatus of FIG. 1. As illustrated, the method comprises (a) a step of forming a resist film, (b) a step of forming a mask from a silicon nitride film, (c) a step of trimming the resist, (d) a step of processing the silicon nitride mask to have a round edge profile; (e) a step of forming a trench for STI, and (f) a step of removing the resist.

In the step of forming a resist film shown in FIG. 2(a), for example, a silicon oxide film 11, a silicon nitride film 12 and a photoresist 13 are formed in the named order on a 12-inch diameter silicon substrate 10. Then, a resist mask having an opening 15 is formed via photolithography technique or the like.

In the step of forming a mask from the silicon nitride film shown in FIG. 2(b), the photoresist 13 is used as mask to etch the silicon nitride film 12 and the silicon oxide film 11 of the opening 15. While performing the etching process, the interface of the silicon substrate 10 is detected via an etching monitor such as an end point detector (EPD). As for processing conditions, for example, the etching is performed using a mixed gas plasma of CF₄ (150 ccm)/CHF₃ (50 ccm) generated by applying 2 Pa process pressure, 1000 W microwaves and 100 W RF bias.

In the step of trimming the resist shown in FIG. 2(c), the pattern of the photoresist 13 is cut back via dry etching so that it is set back from the processed side walls of the opening 15, and the mask edge portion 14 of the silicon nitride film 12 is exposed. As for processing conditions, for example, the etching of the photoresist 13 pattern is performed for a predetermined period of time using a mixed gas plasma of HBr (180 ccm)/O₂ (4 ccm) generated by applying 0.6 Pa process pressure, 600 W microwaves and 20 W RF bias. Based on this process time, the amount of setback of the photoresist 13 can be controlled, and thus the lateral width for providing the round edge profile to the mask of the silicon nitride film 12 can be controlled.

In general, dry etching carried out via application of RF bias is advantageous from the viewpoint of workability and productivity. Through application of the RF bias, the directivity of the incident ions and the energy and flux of the incident ions performing etching are increased, and the processing speed is enhanced. However, excessive application of RF bias may cause etching to proceed to the exposed silicon nitride film 12 and the silicon substrate 10 disposed underneath, so it is preferable to suppress the RF bias to a low value. The degree of effect that the RF bias has on the etching properties varies according for example to the apparatus configuration and process condition such as the electrode structure, the power supply frequency, the plasma density and the etching gas, so it is preferable to select the most appropriate value according to the plasma etching apparatus and etching gas being used.

The pattern of the photoresist 13 can also be cut back in the case where no RF bias is applied. Since the energy and flux of the incident ions can be suppressed to a low value, the damage to the photoresist 13 through ion sputtering can be reduced, and the film thickness reduction of the photoresist 13 can be suppressed. Moreover, accurate processing can be performed at low speed without damaging the exposed silicon nitride film 12 and the silicon substrate 10 disposed underneath.

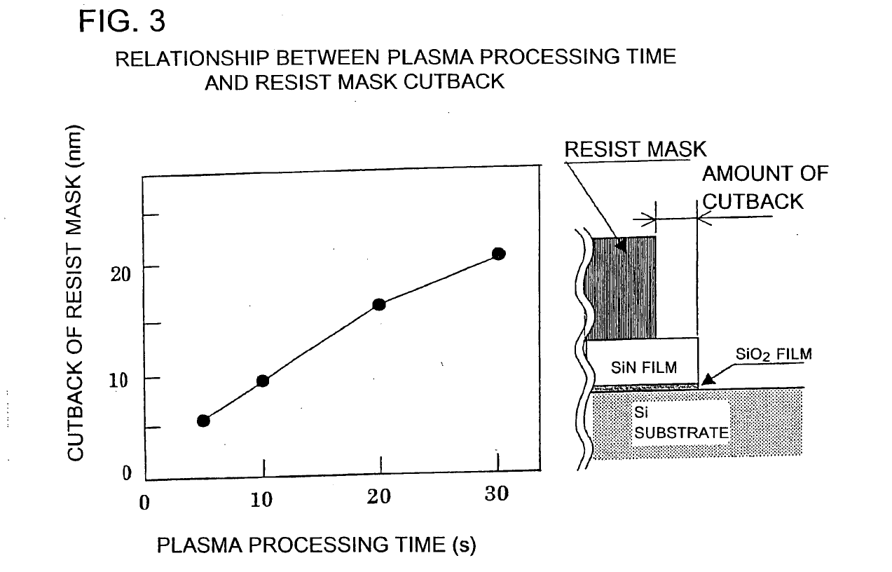

FIG. 3 shows the result of measurement of the amount of cutback of the photoresist 13 to the etching time, in order to evaluate the controllability of the pattern cutback process of the photoresist 13. As shown in the drawing, the photoresist is cut back linearly at a rate of approximately 0.8 nm/sec, so it is understood that the process has sufficient controllability and that the process width of the round profile of the silicon nitride film 12 can be controlled by the etching time.

According to the present embodiment, approximately 2% of O₂ gas is added to the HBr gas flow rate. If the amount of added O₂ gas exceeds 10%, the pattern cutback speed of the photoresist 13 becomes too fast, and it becomes difficult to control the amount of setback of the resist. Moreover, if the amount of O₂ being added is less than 1%, the process will be influenced by the outgas such as O₂ from the components inside the chamber, and the speed of cutback of the pattern of the photoresist 13 becomes unstable. In order to achieve stable workability, it is preferable to add approximately 2 to 9% of O₂ gas.

The etching gas used for cutting back the pattern of the photoresist 13 can be selected from gases such as Cl₂/O₂, HBr/O₂, CF₄/O₂, Ar/O₂, HBr/Ar/O₂, Cl₂/Ar/O₂ and CF₄/Ar/O₂. The gases enable similar processing to be performed, but if it is necessary to put weight on performances such as the controllability of the cutback speed and the workability of the side walls, it is preferable to use HBr/O₂ mixed gas. Further, bromine-containing gases other than HBr, such as Br₂, BrCl and IBr, can be utilized as long as it releases bromine by the dissociation caused by plasma.

Since the main etching gas for cutting back the photoresist 13 is O₂ gas, gases that can be used as the adjustment gas for suppressing etching can include, other than the above-mentioned gases, fluorine-containing gases such as CHF₃, CH₂F₂, C₄F₆, C₄F₈ and C₅F₈, CH₄, CO, and inert gases such as N₂, He, Ne, Ar, Kr and Xe. By adding 1 to 10% O₂ gas to these gases, the resist can be cut back similarly. Similar to the HBr/O₂ based gas, if the amount of added O₂ gas exceeds 10%, the speed of cutback of the pattern of the photoresist 13 becomes too fast, and it becomes difficult to control the amount of setback of the resist. If the amount of added O₂ gas falls below 1%, the speed of cutback of the pattern of the photoresist 13 becomes unstable due to the influence of outgas such as O₂ gas from the components inside the chamber. Since this gas is inexpensive compared to the HBr/O₂ based gas, and since the gas is inert in the steady state, the gas can be handled very safely and the running cost during the process of manufacturing the semiconductor device is suppressed.

In other words, the etching gas for cutting back the pattern of the photoresist 13 can be a mixed gas having 1 to 10% oxygen added to any of the following gases; a chlorine-containing gas, a bromine-containing gas, or a fluorine-containing gas such as CF₄, CHF₃ and CH₂F₂. Moreover, the etching gas for cutting back the pattern of the photoresist 13 can be a mixed gas having 1 to 10% oxygen added to an inert gas such as nitrogen, argon and helium. Furthermore, the etching gas for cutting back the pattern of the photoresist 13 can also be a mixed gas having 1 to 10% oxygen added to a mixed gas containing at least two kinds of gases selected from the following gases; halogen-based gases such as chlorine-containing gas or bromine-containing gas, a fluorine-containing gas such as CF₄, CHF₃ and CH₂F₂, and an inert gas such as nitrogen, argon and helium.

In the step of rounding the edge of the mask formed by the silicon nitride film 12 shown in FIG. 2(d), the edge portion 14 of the mask formed by the silicon nitride film 12 exposed through the trimming step is processed to have a round profile. As for processing conditions, for example, the etching is performed using a CHF₃ (90 ccm) gas plasma generated by applying 0.8 Pa process pressure, 1000 W microwaves and 150 W RF bias. The amount of round-profile processing of the mask edge portion 14 can be controlled by the etching conditions and etching time.

Generally, the energy and flux of the incident ions are controlled via the RF bias being applied, to thereby control the degree of ion sputtering carried out locally to the mask edge portion 14 of the silicon nitride film 12 and to control the round profile. If the RF bias is low, the radius of curvature and the processing speed of the round profile is too small, and sufficient round-profile processing and productivity cannot be achieved. If the RF bias is high, the radius of curvature and the processing speed of the round profile increases, but the controllability deteriorates along with the increase of processing speed, and etching of the silicon substrate 10 underneath the film progresses, affecting the following trench processing. Therefore, it is desirable to seek an appropriate value of the RF bias according to the specification of the trench profile to be processed, that achieves sufficient productivity while suppressing the influence to the lower silicon substrate 10.

Apart from controlling the RF bias, the round profile processing can also be controlled via the amount of O₂ gas and/or N₂ gas being added. During the etching process, CHF₃ gas is dissociated by plasma, generating radicals and ions of carbon, hydrogen and fluoride. These ions and radicals react with the silicon nitride film 12 mask which is the object of etching, generating reaction products. Reaction products with high vapor pressure are evacuated from the vacuum vessel through the evacuation port, but the reaction products with low vapor pressure deposit on the process surface to be etched. The deposits function as a protection film against etching, suppressing the etching speed. If it is extremely thick, the etching may stop. Normally, the deposits adhere thickly on the side surface being processed having smaller ion radiation. If CHF₃ gas is used as etching gas, most of the deposits are formed of components containing carbon, so by adding O₂ gas, the carbon can be evaporated by the reaction of CₓO_{y}, and thus the deposition on the processing surface can be reduced. Further, by adding N₂ gas, nitrides can be generated and the deposition film on the processing surface can be increased. Therefore, by adjusting the amount of O₂ and N₂ being added, the etching speed of the side surface of the mask edge portion 14 can be controlled, and thus the processing profile of the mask edge portion 14 can be controlled. Since the amount of deposits and the effect of removal of the deposition film varies according to the etching gas being used, the flow rate thereof and the etching apparatus being used, it is desirable to seek an appropriate value of the amount of O₂ gas or N₂ gas to be added according to the specification of the trench profile to be processed and the etching apparatus being used.

Moreover, the process profile of the round edge can be controlled by the amount of inert gas such as He, Ne, Ar, Kr and Xe being added. By adding the inert gas, the main etching gas is diluted and excessive etching can be suppressed, according to which the process profile can be controlled appropriately. Further, by adding a gas having a large molecular weight, the effect of ion sputtering can be enhanced and the process profile can be controlled.

According to the present embodiment, CHF₃ gas was used as the process gas for processing the mask formed by the silicon nitride film 12 to have a round edge, but the present invention is not limited to such example. It is also possible to use fluorine-containing gases such as CF₄, CHF₃, CH₂F₂, C₄F₆, C₄F₈ and C₅F₈, or etching gases containing chlorine or bromine such as Cl₂, Br₂, BrCl and IBr, as the process gas. If only a single gas mentioned above is used, it is difficult to obtain selectivity to Si, so the etching of the silicon substrate 10 tends to progress, the range of appropriate conditions is narrowed compared to when CHF₃ gas is used, and the control of the round process profile becomes difficult. However, by mixing at least two of the above-mentioned gases, it becomes possible to generate reaction products such as CBrx (X=1, 2, 3), SiBrₓ (X=1, 2, 3), SiₓBr_{y}O_{z} (X, Y, Z=natural numbers) and SiₓCl_{y}O_{z} (X, Y, Z=natural numbers) having enhanced deposition property or enhanced resistance that was difficult to achieve by using just a single gas, and by havig such reaction products deposit on the processing surface, it becomes possible to control the round profile while securing the selectivity to Si. The protection against etching is enhanced based on this approach, so the RF bias being applied must be increased to enhance the local ion sputtering effect to the edge portion 14 of the mask, but the controllability for processing a round profile can be improved.

In other words, according to the present invention, the round profile processing of the edge portion of the hard mask can utilize at least one or more gases selected from a chlorine-containing gas, a bromine-containing gas or a fluorine-containing gas such as CF₄, CHF₃ and CH₂F₂, or a mixed gas adding to any of the above-listed gases an oxygen gas or an inert gas such as nitrogen, argon and helium.

In the step of processing a trench for STI shown in FIG. 2(e), the trench is formed on the silicon substrate 10 via dry etching using a mask formed by the photoresist 13 and the silicon nitride film 12. As for processing conditions, for example, the etching is performed using a mixed gas plasma of Cl₂ (15 ccm)/HBr (145 ccm)/O₂ (10 ccm) generated by applying 0.4 Pa process pressure, 1000 W microwaves and 100 W RF bias, to form the trench portion.

In the step of removing the resist shown in FIG. 2(f), the photoresist 13 used for processing the trench for STI and the reaction products deposited on the processing surface of etching are removed. By removing the photoresist 13 after etching and processing the STI trench, the edge portion 14 of the mask formed by the silicon nitride film 12 can be processed to have a round profile while maintaining the initial thickness of the mask formed by the silicon nitride film 12 used as the stopper film for chemical-mechanical polishing (CMP) process. Since this approach is not influenced by the etching conditions for the STI trench processing, the fluctuation of finishing film thickness of the silicon nitride film 12 per wafer or per lot can be reduced significantly, and the control of the CMP process becomes facilitated. Further, since the silicon nitride film 12 is not consumed via etching, the initial film thickness of the silicon nitride film 12 as mask can be minimized, and the productivity of the semiconductor device fabrication can be enhanced. Even further, since the aspect ratio of the formed STI trench is stable, it is possible to suppress the occurrence of a cavity during an embedding process, and if the embedding is performed using a high density plasma CVD apparatus, device isolation with advantageous electric properties, good film quality and no cavities can be achieved. Furthermore, the occurrence of processing problems caused by using SiOF film or O₃-TEOS film, such as the hygroscopic property, the instability of electric property and the occurrence of seams during etching, can be avoided. According to the present embodiment, the resist was removed using a resist removing device, but it is possible to remove the resist continuously in the same chamber where the STI trench processing was performed, and this process has no effect on the properties of the device.

In order to carry out the above-mentioned process accurately and stably, it is preferable that the processing apparatus is a multi-chamber type apparatus. By using a vacuum transfer robot disposed at the center of the apparatus to sequentially transfer the object from one dedicated processing chamber disposed circumferentially to another, the influence of the various process gases radiated via the chamber walls used in the previous processing step can be suppressed, and stable processing is realized. According to this method, however, process waiting time at each chamber and wafer inter-chamber transfer time occur, so if it is desirable to emphasize productivity, it is possible to carry out all the processing steps sequentially in a single chamber, according to which it is possible to achieve high productivity proportionate to the number of chambers.

Further, the present invention is capable of dividing and carrying out the processing steps one by one or several steps at a time in different dedicated processing apparatuses. In such case, the process accuracy may become unstable, but the equipment investment can be cut down since existing equipments can be utilized.

The process conditions according to the present embodiment were optimized using test samples of semiconductor devices, and the conditions for etching the silicon nitride film 12, the silicon oxide film 11, the photoresist 13 and the silicon substrate 10 are not limited to the conditions in the present embodiment.

The present invention being applied to an STI technique has been described, but the present invention is not limited thereto, and it can be applied to processes related to forming holes and trenches and embedding substances thereto and to film deposition processes in the field of semiconductor device fabrication, such as deep trench processing and dual damascene processing.

Moreover, round-profile processing is not limitedly applied to silicon nitride films, and can be applied via similar methods to silicon oxide films, SiOC films, SiC films, polysilicon films, metal films such as Ti, W and Al, metal nitride films such as TiN and WN, and silicides such as WSi and MoSi.

Since the processing state of the round profile varies according to the material being processed, it is preferable to seek the appropriate processing conditions and gases to be used according to the material.

Furthermore, the present invention adopted a plasma etching apparatus using microwaves and magnetic field to generate plasma, but the present invention can be applied regardless of how plasma is generated, and equivalent effects of the present invention can be achieved by using, for example, a helicon wave etching apparatus, an inductively-coupled etching apparatus, a capacitively-coupled etching apparatus and so on.

What is claimed is:

1. A dry etching method for forming trenches and holes on a semiconductor substrate, the method comprising processing a hard mask via etching based on a photoresist pattern, cutting back the photo resist pattern via etching to expose an edge portion of the hard mask, and processing the exposed edge portion of the hard mask via etching individually to form a round profile.

2. The dry etching method according to claim 1, wherein the process of cutting back the photoresist pattern utilizes a mixed gas having 1 to 10% oxygen added to a chlorine-containing gas, a bromine-containing gas, or a fluorine-containing gas such as CF₄, CHF₃ and CH₂F₂.

3. The dry etching method according to claim 1, wherein the process of cutting back the photoresist pattern utilizes a mixed gas having 1 to 10% oxygen added to an inert gas such as nitrogen, argon and helium.

4. The dry etching method according to claim 1, wherein the process of cutting back the photoresist pattern utilizes a mixed gas having 1 to 10% oxygen added to a mixed gas containing at least two kinds of gases selected from the group consisting of a halogen-based gas of either a chlorine-containing gas or a bromine-containing gas, a fluorine-containing gas such as CF₄, CHF₃ and CH₂F₂, and an inert gas such as nitrogen, argon and helium.

5. The dry etching method according to claim 1, wherein the process of etching the edge portion of the hard mask to form a round profile utilizes a gas containing one or more gases selected from the group consisting of a chlorine-containing gas, a bromine-containing gas and a fluorine-containing gas such as CF₄, CHF₃ and CH₂F₂, or adding to said one or more gases either oxygen or an inert gas such as nitrogen, argon and helium.
